(19) United States
(12) Patent Application Publication
(10) Pub. No.: US 2026/0227750 A1
(43) Pub. Date: Aug. 6, 2026

(54) HYBRID-COOLED LOAD BANK WITH SOLID-STATE FAST VARYING LOAD SIMULATION

(71) Applicant: Deep Cool AI, Inc., Fremont, CA (US)

(72) Inventors: Davood Ghadiri Moghaddam, Richmond Hill (CA); Kris Holla, Fremont, CA (US); Tikhon Suresh Pichai, Fremont, CA (US)

(73) Assignee: Deep Cool AI, Inc., Fremont, CA (US)

(21) Appl. No.: 19/572,350

(22) Filed: Mar. 19, 2026

Related U.S. Application Data
(63) Continuation-in-part of application No. 19/353,354, filed on Oct. 8, 2025.
(60) Provisional application No. 63/705,799, filed on Oct. 10, 2024.

(51) Int. Cl. G05B 13/04; H05K 7/20

(52) U.S. Cl. CPC G05B 13/04; H05K 7/20272; H05K 7/20781

(57) ABSTRACT

A hybrid-cooled load bank rack with solid-state fast varying load simulator combines liquid-cooled load bank module and air-cooled load bank module within a single rack frame to enable testing of hybrid-cooled data center infrastructures. The hybrid-cooled load bank rack incorporates a solid-state relay switching assembly containing power semiconductor devices, gate driver and snubber network, and inline current sensors to dynamically modulate power delivery according to programmable time-versus-power profiles. A central controller with a programmable load profile engine encodes power demand datasets into control signals and adjusts load allocation between liquid and air cooling paths based on cooling feedback from a CDU feedback interface. A method for simulating fast-varying hybrid-cooled server rack power loads applies programmable power profiles through the solid-state relay switching assembly while monitoring system metrics and streaming real-time power and thermal telemetry to external control systems for coordinated cooling performance analysis.

### CROSS REFERENCE TO RELATED APPLICATIONS

This utility patent application is a Continuation in Part (CIP) of U.S. patent application Ser. No. 19/353,354 filed on Oct. 8, 2025 which claims priority from U.S. patent application 63/705,799 filed on Oct. 10, 2024, the contents of which are incorporated herein as is restated herein.

### TECHNICAL FIELD

This invention relates generally to the field of hybrid-cooled load bank systems for data center power and cooling testing and more specifically to a new and useful hybrid-cooled load bank with solid-state fast varying load simulation in the field of hybrid-cooled load bank systems for data center power and cooling testing.

### BACKGROUND

Data centers have evolved significantly to accommodate increasingly demanding computational workloads, particularly those associated with artificial intelligence training and inference operations. Modern data center infrastructures increasingly employ hybrid cooling architectures that combine both air cooling and liquid cooling to manage the substantial thermal loads generated by high-density server racks. Testing and commissioning such hybrid-cooled infrastructures presents unique challenges that existing load bank technologies have not adequately addressed.

Conventional load bank systems have historically been designed to provide either air cooling or liquid cooling capabilities, but not both within a single integrated apparatus. Data center operators seeking to test hybrid cooling infrastructures have been required to deploy separate air-cooled and liquid-cooled test equipment, complicating commissioning procedures and preventing realistic evaluation of the interactions between electrical loading and both cooling paths simultaneously. The inability to validate hybrid cooling architectures using a unified test system has resulted in incomplete characterization of data center cooling performance prior to deployment of production equipment.

Traditional load banks have also been limited in their ability to replicate realistic power consumption patterns. Existing load bank designs typically provide stepwise load adjustments or simple on/off switching capabilities, producing flat or coarsely stepped power profiles. However, modern AI training and inference workloads exhibit fast-varying, bursty power demand characteristics that differ substantially from the steady-state or gradually changing loads that conventional load banks can simulate. The mismatch between actual server power consumption patterns and the load profiles achievable with existing test equipment has prevented accurate assessment of power distribution and cooling system performance under realistic operating conditions.

The switching mechanisms employed in conventional load bank systems have further constrained the ability to generate dynamic load profiles. Existing systems have generally relied on mechanical contactors or relays that cannot achieve the rapid switching speeds necessary to modulate power delivery according to programmable time-versus-power profiles. The absence of fast-switching solid-state devices in load bank architectures has limited the temporal resolution of achievable load variations and prevented simulation of the rapid power transient's characteristic of modern computational workloads.

Control systems for existing load bank installations have typically provided limited granularity and coordination capabilities. Conventional approaches have not enabled fine-grained, centralized control of multiple-load banks operating across a wide capacity range spanning from tens of kilowatts to megawatt-scale power levels. The lack of coordinated control over both liquid-cooled and air-cooled load elements has prevented operators from executing precise ramping and deramping sequences that would be necessary to characterize cooling system response under varying electrical loads.

Testing methodologies for data center cooling systems have been further constrained by the absence of integrated measurement and control capabilities. Existing test setups have not provided convenient mechanisms for generating arbitrary or real-world server load profiles while simultaneously measuring instantaneous power consumption and communicating power data to cooling distribution unit control systems. The inability to coordinate electrical loading with cooling system operation has prevented comprehensive evaluation of cooling distribution unit response characteristics, including temperature regulation performance, available pressure drops, and behavior under varying liquid and air flow rates.

The physical configuration of existing load bank equipment has also presented obstacles to efficient commissioning of liquid-cooled and hybrid-cooled server rack installations. Conventional load bank systems have not been available as packaged, rack-mounted assemblies that integrate power distribution unit, liquid manifolds, temperature and flow sensors, solid-state switching devices, and programmable controllers within a single enclosure. The requirement to assemble and interconnect separate components for each test installation has increased commissioning time and complexity while introducing potential sources of measurement error and system integration problems.

### SUMMARY

The present invention relates to a hybrid-cooled load bank rack with solid-state fast varying load simulator and an associated method for simulating fast-varying hybrid-cooled server rack power loads. The hybrid-cooled load bank rack integrates liquid-cooled load bank module and air-cooled load bank module within a single rack frame, together with a solid-state relay switching assembly, a power distribution unit, a fluid manifold assembly, a central controller, a sensor suite, a CDU feedback interface, and an external power input interface. The central controller incorporates a programmable load profile engine and a communication interface to orchestrate dynamic power modulation across the load bank modules. The associated method encompasses preparing a hybrid load bank environment, defining a target power profile, applying the power profile through solid-state switching elements, monitoring system metrics, and analyzing cooling performance to generate real-time power and thermal telemetry datasets and cooling performance analysis reports.

The hybrid-cooled load bank rack addresses the limitation of existing load banks that provide only air cooling or only liquid cooling by combining liquid-cooled load bank module and air-cooled load bank module within a unified rack frame. The liquid-cooled load bank module includes a liquid heat exchange assembly, coolant quick-disconnect couplings, and an embedded liquid temperature sensor, while the air-cooled load bank module incorporates resistive heating elements, cooling fans, and airflow and temperature sensors. The integration of both cooling modalities within a single apparatus enables testing and commissioning of hybrid-cooled data center infrastructures without requiring separate test systems for each cooling type. The fluid manifold assembly with flow control valves and pressure/flow sensors further enables coordinated management of liquid cooling paths alongside the air-cooled components.

The invention overcomes the inability of conventional load banks to mimic fast-varying, bursty power demand patterns by incorporating a solid-state relay switching assembly comprising power semiconductor devices, a gate driver and snubber network, and inline current sensors. The power semiconductor devices enable rapid modulation of electrical loads at switching frequencies and response times that substantially exceed the capabilities of mechanical contactors or stepped resistor banks. The programmable load profile engine within the central controller encodes power demand datasets into control signals that drive the solid-state relay switching assembly, thereby reproducing the transient power characteristics of AI training and inference server racks with temporal resolution in the sub-second range.

The hybrid-cooled load bank rack provides integrated fast-switching solid-state relays to dynamically modulate power delivery according to programmable time-versus-power profiles. The solid-state relay switching assembly receives encoded SSR control signal set from the programmable load profile engine and modulates power through the switching elements to generate applied electrical load pattern. The gate driver and snubber network conditions switching transitions to reduce electromagnetic interference and protect the power semiconductor devices during rapid load changes. The inline current sensors provide real-time feedback to the central controller, enabling closed-loop control of the instantaneous power delivered to the load bank modules.

The invention enables realistic evaluation of the interaction between variable electrical loading and both liquid and air cooling paths within a single rack-level apparatus. The central controller executes a balance liquid and air load allocation step that distributes power demand across the liquid-cooled load bank module and air-cooled load bank module according to configurable ratios or thermal constraints. The adjust load based on cooling feedback step modifies the power distribution in response to temperature, pressure, and flow measurements from the sensor suite and the CDU feedback interface. The simultaneous operation of both cooling modalities under dynamically varying electrical loads validates hybrid cooling architectures under conditions representative of actual server rack deployments.

The hybrid-cooled load bank rack provides fine-grained, centralized control of multiple liquid and air-cooled load banks to enable granular ramping and deramping of power across capacity ranges spanning approximately 100 kW to greater than 1 MW. The power distribution unit routes electrical power from the external power input interface to the individual load bank modules under the direction of the central controller. The programmable load profile engine generates control sequences that incrementally adjust the power delivered to each module, enabling smooth transitions between load levels without the discrete steps characteristic of mechanically switched load banks. The sensor suite comprising power measurement sensors, temperature sensors, and pressure sensors provides the feedback necessary for precise load control across the full capacity range.

The invention provides a convenient mechanism to generate and apply arbitrary or real-world server load profiles while simultaneously measuring instantaneous power and feeding measurements to cooling distribution unit control systems. The acquire or generate power demand dataset step accepts programmable power-load profile derived from recorded server telemetry or synthetic workload models. The encode dataset into control signals step transforms the power demand dataset into encoded SSR control signal set compatible with the solid-state relay switching assembly. The capture instantaneous electrical load data step and the stream data to external control systems step deliver real-time power and thermal telemetry datasets to external CDU controllers through the communication interface, enabling coordinated testing of power and cooling infrastructure.

The hybrid-cooled load bank rack supports characterization of cooling distribution systems under varying electrical loads by correlating load and thermal data to determine cooling limits and response characteristics. The monitor system metrics step captures cooling system parameter datasets including liquid temperatures, flow rates, pressures, airflow velocities, and air temperatures from the embedded liquid temperature sensor, the pressure/flow sensors, and the airflow and temperature sensors. The correlated load and thermal data step generates load-thermal correlation metrics that quantify the relationship between electrical power dissipation and thermal response. The determined cooling limits and response step produces cooling limit and response datasets that characterize available pressure drops, temperature rise rates, and cooling capacity under differing liquid and air flow rates and temperatures.

The invention addresses the absence of packaged, rack-mounted hybrid load bank equipment by integrating power distribution unit, fluid manifold assembly, sensors, solid-state switches, and controllers within a single rack frame. The prepare hybrid load bank environment step encompasses configuring load bank composition, connecting power and cooling interfaces, and initializing sensors and controllers to establish a prepared hybrid load bank environment. The configured hybrid load bank composition, power and cooling interfaces connected, and sensors and controllers initialized configurations collectively establish a hybrid load bank ready state that enables immediate execution of load simulation sequences. The integration of all functional subsystems within a unified enclosure reduces installation complexity, minimizes interconnection requirements, and accelerates commissioning of liquid-cooled and hybrid-cooled AI server rack infrastructures.

### BRIEF DESCRIPTION OF FIGURES

FIG. 1 is a graph representation of a sample simulated load profile for a hybrid load bank using SSRs.

FIG. 2 is a graph representation of another sample simulated load profile for the Hybrid Load Bank with SSRs.

FIG. 3 is a front view of three parts of a hybrid load bank, showing both liquid and air-cooled units. Sometime referred to as option 1.

FIG. 4 is a afront view of a hybrid load bank, showing both liquid and air-cooled units in an IT rack. Includes SSR Switch.

FIG. 5 Is a perspective view of a Hybrid load bank, showing both liquid and air-cooled units in an IT rack with PDUs, Manifolds and all necessary power and water connections inside the IT Rack. This configuration is sometimes referred to as option 2.

FIG. 6 is a perspective view example of 12 kW Rack-mount Air cooled load banks.

FIG. 7 is a perspective view example of 20 kW rack-mount liquid cooled load banks.

FIG. 8 is a perspective view example of 110 kW liquid cooled load banks.

### DETAILED DESCRIPTION

### Hybrid-Cooled Load Bank Rack With Solid-State Fast Varying Load Simulator

A hybrid-cooled load bank rack with solid-state fast varying load simulator can include both air-cooled and liquid-cooled electrical load banks integrated within a single rack-mounted enclosure. Generally, the hybrid-cooled load bank rack can include fast-switching solid-state relays and/or equivalent solid-state power modulation devices electrically coupled to one or more of the load banks to enable rapid modulation of power delivery. The hybrid-cooled load bank rack can further include power distribution unit, fluid handling manifolds for liquid coolant distribution, air handling systems, electrical power connections, and/or a centralized control system. More specifically, the centralized control system can receive programmable and/or real-time control signals and can modulate power delivered to each load bank according to predefined and/or dynamically generated time-versus-power profiles, including profiles that mimic fast-varying, burst-type power demands characteristic of AI training and/or inference server racks. Additionally, the hybrid-cooled load bank rack can include sensors configured to measure instantaneous power consumption, temperature, pressure, and/or flow rates at various points within the system, and the measured data can be transmitted to external cooling distribution unit controllers and/or other facility management systems. In one implementation, the hybrid-cooled load bank rack can operate across a capacity range (e.g., from approximately 100 kW to at least 1 MW) and can support various proportions and/or arrangements of air-cooled and liquid-cooled load banks. Thus, by integrating both cooling modalities and fast-switching solid-state relay control within a single rack-level apparatus, the hybrid-cooled load bank rack addresses the challenge of testing hybrid-cooled data center infrastructures and enables simulation of arbitrary and/or real-world server rack power demand profiles while supporting characterization of cooling system performance under variable electrical and thermal loading conditions.

### Rack Frame

Generally, the rack frame can serve as a structural assembly configured to support and house components of the hybrid-cooled load bank system within a single integrated enclosure. In one implementation, the rack frame can be a standard 19-inch IT equipment rack, while in another implementation, the rack frame can be a custom-fabricated welded frame. The rack frame can have dimensions and load-bearing capacity suitable for accommodating power dissipation levels across a range (e.g., from approximately 100 kW to over 1 MW). More specifically, the rack frame can provide mounting rails, brackets, and/or support structures for securely attaching air-cooled load bank module, liquid-cooled load bank module, power distribution unit, fluid manifold assembly, solid-state relay switching assembly, sensors, and/or control electronics. The rack frame can incorporate provisions for cable management, including dedicated ingress and/or egress points for electrical power cables, control wiring, and/or network connections. Additionally, the rack frame can include pipe or hose entry points for liquid cooling circuits, with optional sealing and/or grommet features to maintain environmental separation. The rack frame can be configured to maintain mechanical stability under the combined weight of installed modules and/or to withstand thermal cycling and/or vibration encountered during high-power operation. In one embodiment, the rack frame can be equipped with leveling feet, casters, and/or anchoring points to facilitate installation in data center environments and/or test facilities. Alternatively, the rack frame can include removable side panels, doors, and/or access covers to enable serviceability and/or reconfiguration of internal components.

### Liquid-Cooled Load Bank Module

Generally, the hybrid-cooled load bank rack with solid-state fast varying load simulator can include a liquid-cooled load bank module. The liquid-cooled load bank module can comprise a rack-mountable assembly configured to convert electrical power into heat, which a circulating liquid coolant subsequently removes. In one implementation, the liquid-cooled load bank module can include a resistive heating element or an array of resistive heating elements thermally coupled to a liquid-cooled enclosure (e.g., a cold plate and/or liquid jacket) that interfaces with facility coolant loops. The liquid-cooled load bank module can be produced in a range of power ratings (e.g., 20 kW, 110 kW, or higher) to accommodate various testing capacities and/or facility requirements. Additionally, the liquid-cooled load bank module can be controlled by the central controller to enable programmable, time-varying power profiles that mimic real-world server rack power consumption patterns, including rapid ramping and/or deramping of load.

### Air-Cooled Load Bank Module

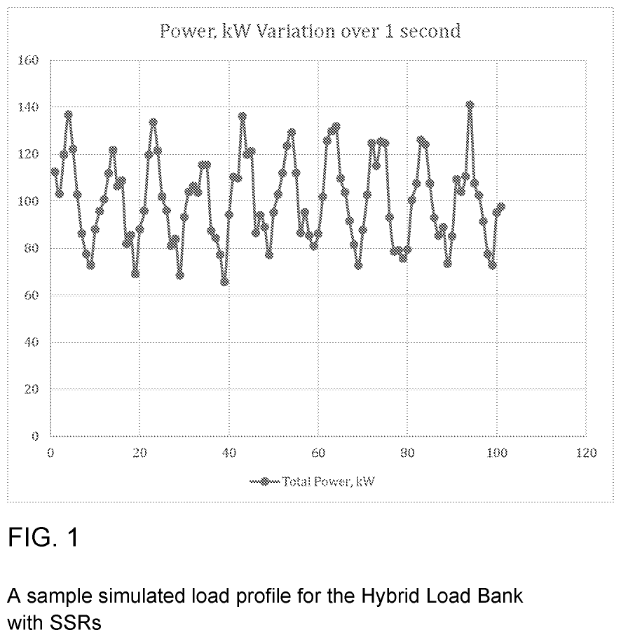

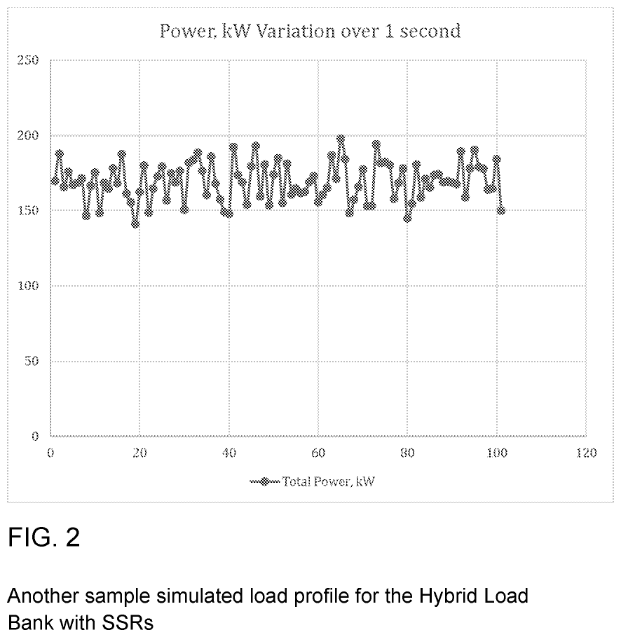

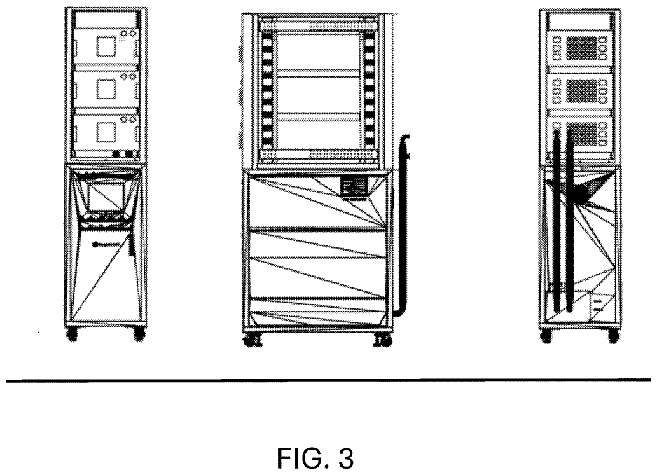

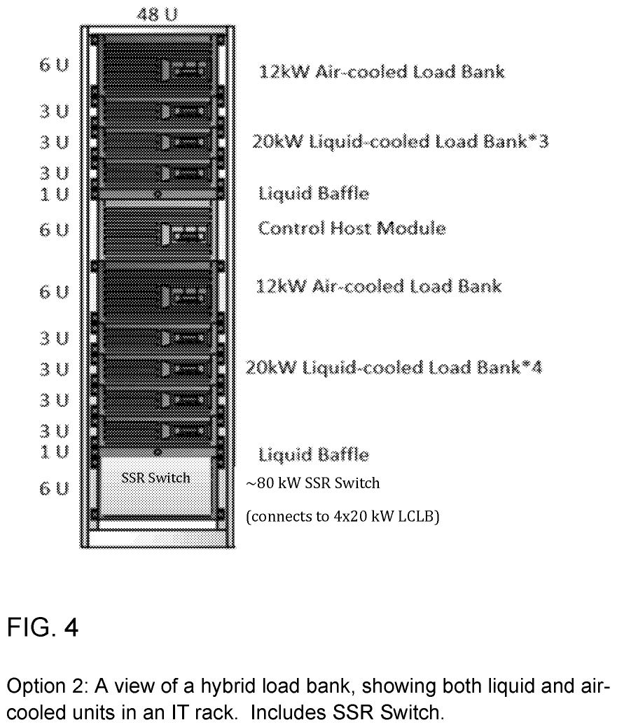

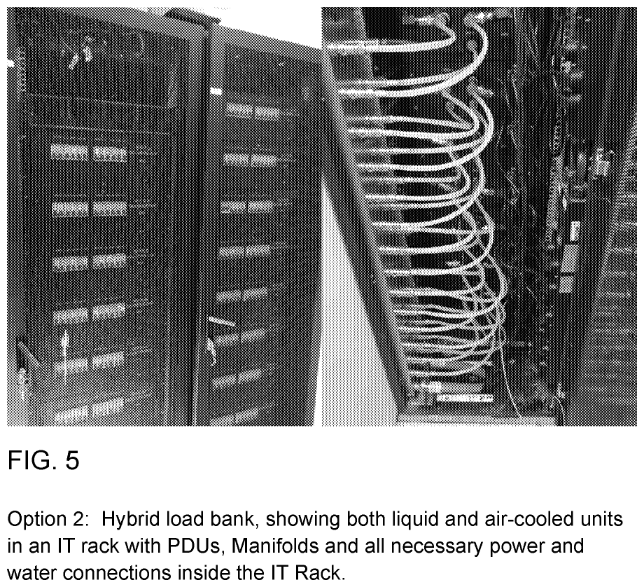

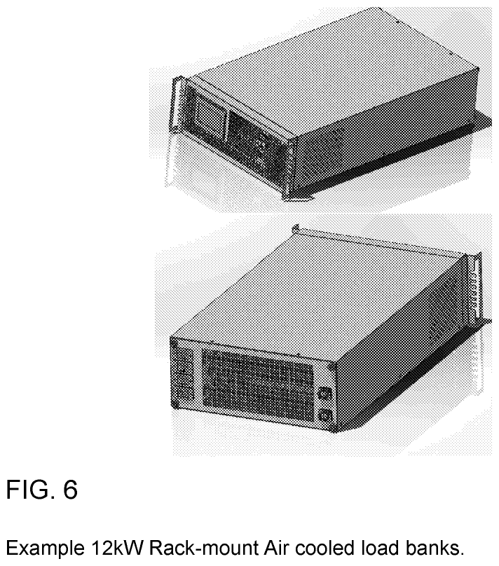

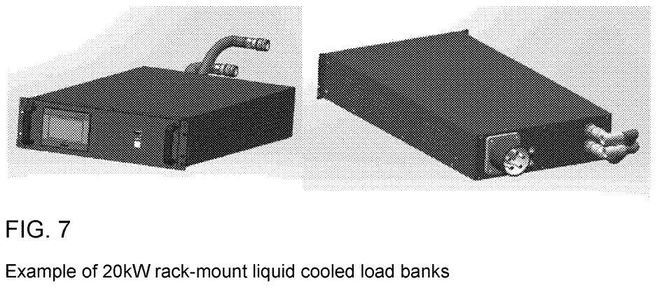

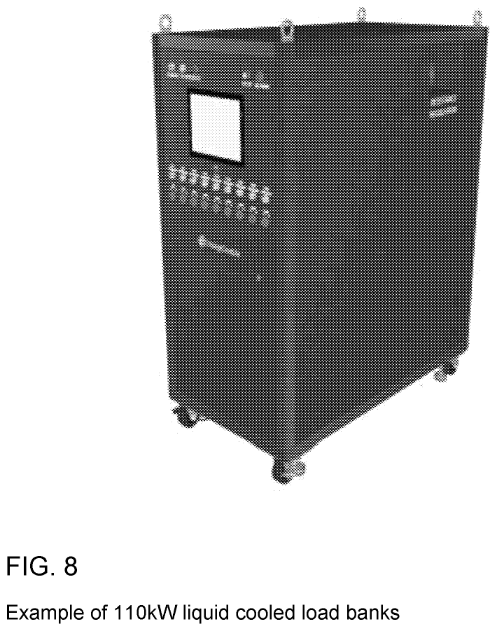

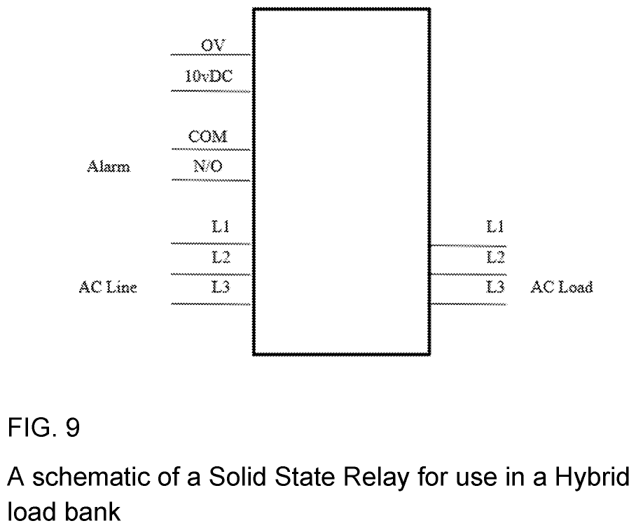

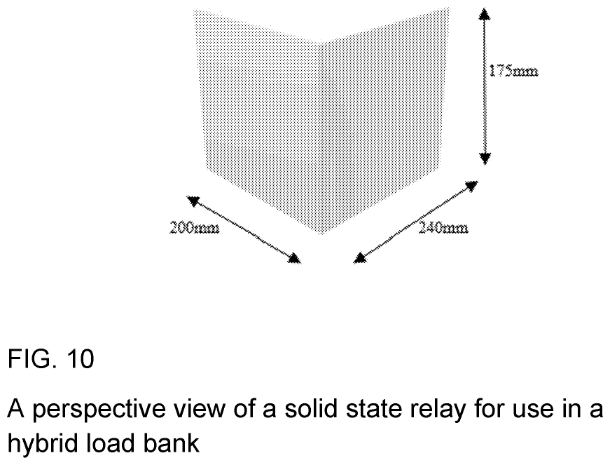

Generally, the hybrid-cooled load bank rack with solid-state fast varying load simulator can include an air-cooled load bank module configured to dissipate electrical power as heat using forced air convection. As shown in FIG. 1, the air-cooled load bank module can comprise a housing configured for installation within the rack frame, the housing containing resistive heating elements electrically connected to the power distribution unit. The air-cooled load bank module can include cooling fans integrated within the housing to direct ambient air across the resistive heating elements, thereby transferring heat generated by electrical loading to an exhaust air stream. Additionally, the air-cooled load bank module can incorporate airflow and temperature sensors for monitoring inlet air temperature, outlet air temperature, and/or airflow rate, enabling real-time assessment of thermal performance and cooling effectiveness. In one implementation, the air-cooled load bank module can be rated for a nominal power dissipation capacity (e.g., between approximately 10 kW and approximately 15 kW per module), and multiple air-cooled load bank module can be installed in parallel within the rack frame to achieve aggregate load capacities (e.g., up to or exceeding 1 MW). The air-cooled load bank module can operate independently and/or in conjunction with the liquid-cooled load bank module, allowing for flexible configuration of air and liquid cooling proportions during hybrid-cooled infrastructure testing.

### Airflow and Temperature Sensors

Generally, the air-cooled load bank module can include airflow and temperature sensors configured to monitor and report air-side thermal and flow parameters during load testing operations. In one implementation, the airflow and temperature sensors can include differential pressure taps positioned across airflow paths to determine volumetric airflow rates, and/or thermistors or resistance temperature detectors (RTDs) placed at air inlet and/or outlet locations to measure temperature differentials across the load banks. The airflow and temperature sensors can provide real-time data on airflow volume and/or temperature gradients, enabling calculation of heat removal rates and assessment of air cooling effectiveness. Additionally, sensor outputs of the airflow and temperature sensors can be transmitted to the central controller and/or a data acquisition system for logging, analysis, and/or feedback control of cooling system operation. In one embodiment, the airflow and temperature sensors can be calibrated to operate across a range of airflow rates (e.g., between approximately 0 and 5000 CFM) and/or temperature differentials (e.g., between approximately 0 and 40° C.), supporting both steady-state and/or transient testing scenarios. Alternatively or additionally, the airflow and temperature sensors can be networked and/or addressable for integration with automated test scripts and/or remote monitoring systems.

### Solid-State Relay Switching Assembly

A disclosed hybrid-cooled load bank rack with solid-state fast varying load simulator can include a solid-state relay switching assembly configured to provide rapid, programmable switching of electrical power to load modules within the rack. Generally, the solid-state relay switching assembly can comprise one or more banks of solid-state relays arranged to selectively connect and/or disconnect air-cooled load bank module and/or liquid-cooled load bank module in accordance with control signals received from the central controller. The solid-state relay switching assembly can achieve switching response times (e.g., sub-millisecond response times) that enable emulation of fast-varying, burst-type power demand profiles characteristic of AI training and inference server workloads. In one implementation, the solid-state relay switching assembly can include zero-cross controlled solid-state relays and/or phase-angle controlled solid-state relays, which can be rated for operation at voltages up to a target operating voltage (e.g., up to 480 V) and currents up to a target current rating (e.g., up to 200 A per pole). Additionally or alternatively, the solid-state relay switching assembly can be implemented as a modular subsystem that supports expansion to accommodate additional load modules and/or increased total system capacity. The solid-state relay switching assembly can further include thermal management features, such as heat sinks and/or forced-air cooling, to maintain operational reliability under high switching frequencies and/or elevated load currents. Thus, the solid-state relay switching assembly addresses the challenge of accurately mimicking fast-varying, bursty power demand patterns by enabling dynamic modulation of power delivery according to programmable time-versus-power profiles within a single integrated hybrid-cooled test apparatus.

### Power Semiconductor Devices

Generally, the solid-state relay switching assembly can include power semiconductor devices configured to modulate electrical power delivery to one or more load banks within the hybrid-cooled load bank rack. In one implementation, the power semiconductor devices can comprise solid-state switching elements such as triacs, metal-oxide-semiconductor field-effect transistors (MOSFETs), and/or insulated-gate bipolar transistors (IGBTs). The power semiconductor devices can be mounted on heat sinks that utilize forced-air cooling, liquid cooling, or a combination thereof, to dissipate switching losses and/or conduction losses generated during operation. More specifically, the power semiconductor devices can be arranged to enable rapid, programmable switching of load bank circuits in response to control signals from the central controller, thereby facilitating simulation of fast-varying power demand profiles. The power semiconductor devices can be selected and dimensioned to accommodate a range of load bank capacities (e.g., from approximately 100 kW to over 1 MW), and can be integrated with sensors to monitor temperature, current, and/or voltage for protection and feedback control. Thus, the power semiconductor devices can address the inability of conventional load banks to accurately mimic fast-varying, bursty power demand patterns by providing rapid switching capability for dynamic power modulation across both liquid-cooled and air-cooled load paths.

### Gate Driver and Snubber Network

Generally, the solid-state relay switching assembly can include a gate driver and snubber network configured to interface with the power semiconductor devices. The gate driver and snubber network can comprise optically isolated gate driver circuits and/or resistor-capacitor (RC) snubber assemblies. More specifically, the gate driver circuits can receive control signals from the central controller and provide galvanic isolation between a low-voltage control domain and a high-voltage power switching domain. The gate driver circuits can deliver rapid turn-on and turn-off transitions, achieving switching times within a target range (e.g., less than approximately 1 millisecond), which can enable simulation of fast-varying load profiles. Additionally, the RC snubber network can be electrically connected in parallel with each solid-state switch to suppress voltage transients and/or mitigate switching-induced electromagnetic interference (EMI), thereby protecting the power semiconductor devices from overvoltage stress during high-frequency switching events. In one implementation, component values of the gate driver and snubber network can be selected based on voltage, current, and/or switching frequency requirements of the load bank modules. Further, the gate driver and snubber network can include diagnostic and/or monitoring features configured to detect abnormal switching behavior and/or component degradation.

### Inline Current Sensors

Generally, the solid-state relay switching assembly can include inline current sensors positioned within the power delivery paths of the hybrid-cooled load bank rack with solid-state fast varying load simulator. The inline current sensors can utilize various current-sensing technologies, such as Hall-effect transducers and/or shunt resistors, to provide real-time measurement of electrical current supplied to individual load banks and/or sub-circuits. In one implementation, the inline current sensors can be configured for high-speed sampling to capture rapid load transitions enabled by the power semiconductor devices, thereby supporting simulation of bursty and/or fast-varying power loads characteristic of AI training and/or inference workloads. The inline current sensors can transmit measured current data to the central controller, where the data can be used to calculate instantaneous power consumption, enable closed-loop feedback control, and/or facilitate generation of time-varying load profiles.

### Power Distribution Unit

Generally, the hybrid-cooled load bank rack with solid-state fast varying load simulator can include a power distribution unit. The power distribution unit can receive facility power and distribute electrical energy to downstream components within the hybrid-cooled load bank system. In one implementation, the power distribution unit comprises integrated circuit breakers, contactors, and/or bus bars that route electrical power to solid-state relay switching assembly and/or individual load modules, including air-cooled load bank module and/or liquid-cooled load bank module. The power distribution unit can provide over-current protection for each branch circuit and/or incorporate branch-level electrical metering to monitor current, voltage, and/or power delivered to each load bank. Additionally, the power distribution unit can include remote monitoring and/or control interfaces, enabling integration with the central controller for coordinated operation and/or safety interlocks. In one embodiment, the power distribution unit can be configured to support a range of total system capacities (e.g., from approximately 100 kW to over 1 MW) and/or adapted to accommodate single-phase and/or three-phase power input. Further, the power distribution unit can include provisions for hot-swappable connections, redundant power feeds, and/or integration with facility emergency power-off systems.

### Fluid Manifold Assembly

Generally, the fluid manifold assembly can comprise a set of supply and return manifolds configured to distribute and collect coolant for one or more liquid-cooled load bank module within the hybrid-cooled load bank rack with solid-state fast varying load simulator. In one implementation, each manifold of the fluid manifold assembly can incorporate flow-balancing valves that enable adjustment of coolant flow rates to individual load bank modules, thereby facilitating precise control of thermal management across varying load conditions. The fluid manifold assembly can be constructed to accommodate glycol-water coolant mixtures at temperatures up to a threshold temperature (e.g., 80° C.) and/or can be compatible with a range of flow rates suitable for load banks operating from a minimum capacity (e.g., 100 kW) to a maximum capacity (e.g., over 1 MW). Additionally or alternatively, the fluid manifold assembly can include quick-connect fittings, isolation valves, and/or one or more sensors to support rapid installation, monitoring, and/or maintenance of the fluid manifold assembly.

### Central Controller

Generally, the hybrid-cooled load bank rack with solid-state fast varying load simulator can include a central controller configured to coordinate operation of the various load bank modules and switching assemblies. The central controller can comprise an embedded computing device and/or a programmable logic controller (PLC) that generates and transmits control signals to the solid-state relay switching assembly, thereby modulating electrical power delivered to the liquid-cooled load bank module and/or the air-cooled load bank module according to time-versus-power profiles. More specifically, the central controller can receive input signals from the sensor suite, including temperature, flow, pressure, and/or electrical power measurements, and can continuously monitor these signals to log operational data, detect system states, and enable closed-loop and/or open-loop control of load bank operation. The central controller can also interface with external orchestration software and/or facility management systems via standard communication protocols (e.g., Ethernet, Modbus, OPC-UA), enabling remote configuration, monitoring, and integration with cooling distribution unit control systems. Thus, the central controller addresses the technical challenge of providing fine-grained, centralized control of multiple liquid and air-cooled load banks to enable granular ramping and deramping of power across a wide capacity range (e.g., 100 kW to over 1 MW) while simultaneously coordinating both cooling paths within a single integrated apparatus.

### CDU Feedback Interface

Generally, the hybrid-cooled load bank rack with solid-state fast varying load simulator can include a CDU feedback interface. The CDU feedback interface can comprise an electrical and/or data communication subsystem configured to transmit real-time measurements of instantaneous electrical load to an external cooling distribution unit (CDU). In one implementation, the CDU feedback interface can include analog signal pathways, such as analog voltage and/or current outputs, and/or digital signal pathways, such as Ethernet and/or RS-485 connections. Alternatively, the CDU feedback interface can support wireless communication protocols. The CDU feedback interface can be operable to convey load data at a frequency (e.g., between approximately 10 Hz and 1 kHz) sufficient to enable dynamic adjustment of coolant flow rates by the CDU in response to rapid changes in simulated server rack power consumption. In one embodiment, the CDU feedback interface can be integrated with the central controller of the hybrid-cooled load bank rack, which can aggregate and/or format the load data for transmission. Additionally or alternatively, the CDU feedback interface can support bidirectional communication, allowing the CDU to send control signals and/or status signals back to the hybrid-cooled load bank rack. The CDU feedback interface can be configured to comply with standard industrial communication protocols and/or custom formats, and can provide instantaneous, averaged, and/or time-stamped load data, thereby enabling coordinated, closed-loop control of cooling parameters in hybrid-cooled data center test environments.

### External Power Input Interface

Generally, the hybrid-cooled load bank rack with solid-state fast varying load simulator can include an external power input interface. The external power input interface can comprise one or more terminal blocks, busway connectors, and/or other high-capacity electrical interfaces configured to receive three-phase facility power at a target voltage (e.g., 208 V or 415 V). In one implementation, the external power input interface can accommodate total system power requirements ranging from approximately 100 kW up to at least 1 MW, thereby enabling the hybrid-cooled load bank rack to operate across a broad range of test scenarios. The external power input interface can provide a secure and electrically robust connection point for facility power, supporting both continuous and rapidly varying load conditions. Additionally, the external power input interface can include features such as phase monitoring, overcurrent protection, and/or compatibility with standard data center power distribution architectures. In some embodiments, the external power input interface can be configured to support redundant power feeds and/or hot-swappable connections to facilitate uninterrupted operation during maintenance or reconfiguration. Further, the external power input interface can be electrically coupled to downstream components of the hybrid-cooled load bank rack, such as the power distribution unit, the solid-state relay switching assembly, and/or the liquid-cooled and air-cooled load bank module, thereby enabling precise and programmable modulation of power delivery throughout the system.

### Method for Simulating Fast-Varying Hybrid-Cooled Server Rack Power Loads

Generally, the method for simulating fast-varying hybrid-cooled server rack power loads can orchestrate a hybrid-cooled load bank rack to reproduce rapid, variable power consumption profiles representative of AI training and/or inference server racks. The method can exercise both liquid and air cooling subsystems simultaneously within a single rack-mounted apparatus. In one implementation, the method receives a programmable power-load profile as input and generates a real-time power and thermal telemetry dataset and/or a cooling performance analysis report as output. The method can support repeatable, automated test cycles across a capacity range (e.g., 100 kW to 1+ MW), enabling characterization of cooling system performance under varying electrical loads, including measurement of response times for temperature changes, available pressure drops, and/or performance under differing liquid and air flow rates and temperatures. Thus, the method addresses the challenge of validating hybrid cooling architectures by enabling realistic evaluation of the interaction between variable electrical loading and both liquid and air cooling paths in a single integrated test system.

### Prepare Hybrid Load Bank Environment

Generally, the method for simulating fast-varying hybrid-cooled server rack power loads can include preparing a hybrid load bank environment. In one implementation, the rack frame can receive a combination of liquid-cooled load bank module and/or air-cooled load bank module selected according to a target power capacity (e.g., between approximately 100 kW and 1 MW or more). The central controller can verify the integrity of fluid manifolds and power connections, such as by initiating leak checks and/or pressure tests prior to load simulation. Thus, preparing the hybrid load bank environment can establish a prepared hybrid load bank environment that enables subsequent application of power profiles and/or monitoring of system metrics.

### Configure Load Bank Composition

Generally, configuring the load bank composition can include selecting and/or establishing a proportion of liquid-cooled load bank module relative to air-cooled load bank module within the hybrid-cooled load bank rack. In one implementation, the central controller can configure the composition by electronically enabling and/or disabling specific load bank modules according to a target server rack configuration. Alternatively, the composition can be configured by physically installing and/or removing liquid-cooled load bank module and/or air-cooled load bank module within the rack frame. The central controller can set a ratio of liquid-cooled capacity to air-cooled capacity (e.g., approximately 70% liquid-cooled and approximately 30% air-cooled) to correspond to a cooling architecture of a system under test. Additionally, the composition can be adjusted to accommodate a range of total power capacities (e.g., from approximately 100 kW to over 1 MW) and/or to support various hybrid cooling scenarios. In one embodiment, the central controller can perform the configuration prior to test execution and/or dynamically during operation depending on requirements of a simulation protocol. Thus, configuring the load bank composition can enable the hybrid-cooled load bank rack to accurately replicate cooling and/or power distribution characteristics of server racks employing mixed cooling technologies.

### Connect Power and Cooling Interfaces

Generally, the power distribution unit and/or the fluid manifold assembly can connect power and cooling interfaces to enable electrical and thermal connectivity between the hybrid-cooled load bank rack with solid-state fast varying load simulator and external infrastructure. More specifically, the power distribution unit can attach to electrical input terminals of the load bank via appropriate conductors, and the fluid manifold assembly can couple liquid cooling manifolds to inlets and outlets of the liquid-cooled load bank module through coolant quick-disconnect couplings. Additionally or alternatively, airflow guides can direct ambient or conditioned air through the air-cooled load bank module. In one implementation, the system can verify that liquid flow rate, liquid temperature, and/or electrical voltage at respective interfaces meet predefined setpoints (e.g., a target flow rate between approximately 10 and 50 liters per minute, an inlet temperature between approximately 15 and 35 degrees Celsius, and/or a supply voltage within a tolerance such as plus or minus 2 percent of nominal) prior to subsequent load simulation. Further, the system can confirm integrity of all connections to reduce the likelihood of leaks and/or electrical faults, and can optionally accommodate different rack layouts and/or cooling fluid types. This step can result in a power and cooling interfaces connected configuration that enables subsequent initialization of sensors and controllers.

### Initialize Sensors and Controllers

Generally, the central controller can initialize the sensing and control infrastructure of the hybrid-cooled load bank rack prior to executing any load simulation. More specifically, the central controller can power on and boot a control system, such as a programmable logic controller, an industrial PC, and/or a microcontroller-based system, configured to manage load bank operation. The central controller can address and establish communication with each solid-state relay of the solid-state relay switching assembly, ensuring that each relay is uniquely identified and responsive to control commands. Additionally, the central controller can calibrate all power measurement sensors associated with the load banks, which can include setting zero points, verifying measurement accuracy against known standards, and/or configuring scaling factors for real-time power monitoring. Further, the central controller can perform zeroing and/or baseline calibration of all temperature sensors and pressure sensors integrated into the hybrid-cooled load bank rack, including sensors located at liquid coolant inlets and outlets, air flow paths, and/or within the load bank modules. In one implementation, the initialization process can include self-diagnostic routines to verify sensor and controller functionality, logging of initial baseline data, and/or establishing communication links with external systems such as a cooling distribution unit controller or facility management systems via the CDU feedback interface and/or the communication interface. The initialization step can be performed automatically upon system startup and/or manually via a user interface, and can be repeated as needed to maintain measurement accuracy throughout testing cycles, thereby resulting in a sensors and controllers initialized configuration.

### Define Target Power Profile

Generally, the method for simulating fast-varying hybrid-cooled server rack power loads can include defining a target power profile. The programmable load profile engine can generate and/or import a time-resolved dataset specifying a desired power consumption pattern to be simulated by the hybrid-cooled load bank system. The target power profile can represent real-world server workload behaviors, such as those observed in AI training and/or inference operations, and can include arbitrary and/or pre-recorded time-versus-power curves, step changes, and/or bursty demand patterns. In one implementation, the programmable load profile engine can translate the target power profile into a sequence of control signals and/or switching commands compatible with solid-state relays and/or equivalent fast-switching devices integrated within the load bank rack. More specifically, the translation process can involve mapping desired power levels at each time interval to corresponding SSR activation states, pulse-width modulation parameters, and/or other control variables that modulate the electrical load applied to one or more air-cooled and/or liquid-cooled load bank module. The method can further include validating the generated control sequence for compatibility with electrical and/or thermal limits of the system, and can optionally adjust the profile to account for system response times, SSR switching speeds, and/or safety constraints. Thus, the defined target power profile step addresses the challenge of accurately mimicking fast-varying, bursty power demand patterns characteristic of modern AI server racks by enabling arbitrary and/or real-world server load profiles to be generated and applied to a hybrid-cooled test rack.

### Acquire or Generate Power Demand Dataset

Generally, the programmable load profile engine can acquire or generate a power demand dataset representative of fast-varying server rack loads. In one implementation, the programmable load profile engine can retrieve historical telemetry data from AI training and/or inference server operations, wherein the data comprises time-resolved power consumption profiles with sub-second granularity (e.g., millisecond-level resolution). Alternatively or additionally, the programmable load profile engine can algorithmically synthesize power demand curves that simulate rapid load transitions, such as linear ramps from an idle power level to a rated load within a target transition period (e.g., less than 50 milliseconds), and/or periodic square-wave bursts at specified duty cycles and amplitudes. More specifically, the power demand dataset can include arbitrary and/or user-defined time-versus-power patterns, including stochastic, deterministic, and/or hybrid profiles, to enable simulation of real-world operational scenarios and/or stress-test conditions. The resulting programmable power-load profile can be formatted for compatibility with the central controller, thereby enabling subsequent steps to utilize the programmable power-load profile for dynamic modulation of load bank power delivery.

### Encode Dataset Into Control Signals

Generally, the programmable load profile engine can encode the power demand dataset into control signals suitable for driving the solid-state relay switching assembly. More specifically, the programmable load profile engine can transform each power set-point within the dataset into a sequence of electrical control instructions that modulate a conduction state of one or more power semiconductor devices with sub-millisecond temporal resolution. In one implementation, the encoding can utilize pulse-width modulation, wherein the programmable load profile engine maps each power set-point to a duty cycle value that determines a proportion of time a corresponding solid-state relay remains in a conducting state within each modulation period. Alternatively, the encoding can utilize phase-angle control, wherein the programmable load profile engine converts each set-point into a phase delay relative to an AC waveform to control effective power delivered to a load bank module. In yet another implementation, the encoding can utilize discrete on/off gating, wherein the programmable load profile engine compares each set-point to a threshold and/or time-varying reference to generate binary switching instructions. The programmable load profile engine can apply signal conditioning, filtering, and/or dithering to the control signals to minimize switching artifacts and/or to ensure accurate reproduction of rapid load transitions. The encoded SSR control signal set can be generated with temporal granularity (e.g., microsecond or sub-millisecond intervals) sufficient to enable accurate simulation of fast-varying and/or bursty power demand patterns characteristic of AI training and inference workloads. Thus, the encoding addresses the challenge of replicating realistic server power profiles by translating arbitrary power demand datasets into precise switching instructions that enable the hybrid-cooled load bank rack to dynamically modulate power delivery according to programmable time-versus-power profiles.

### Apply Power Profile

Generally, applying a power profile can include controlling the activation and/or deactivation of individual load-bank modules in accordance with encoded control signals derived from the programmable power-load profile. The central controller and/or the solid-state relay switching assembly can execute the encoded SSR control signal set to modulate conduction states of the power semiconductor devices, thereby enabling rapid transitions in power delivery to each load-bank module. In one implementation, the encoded control signals can represent a desired instantaneous power demand that corresponds to real-world server rack workloads and/or arbitrary programmable patterns. The central controller can distribute the total power demand between liquid-cooled load bank module and/or air-cooled load bank module according to a predetermined and/or dynamically adjustable liquid-to-air load split ratio. Additionally or alternatively, the central controller can synchronize switching actions across multiple solid-state relays to minimize electrical transients and/or ensure accurate tracking of the target power profile. In one embodiment, the step of applying the power profile can be executed for a range of total rack power capacities (e.g., between approximately 100 kW and over 1 MW), and can support predefined and/or on-demand power profile patterns. Thus, applying the power profile addresses the challenge of mimicking fast-varying, bursty power demand patterns characteristic of AI training and inference workloads while enabling coordinated testing of hybrid cooling architectures under realistic electrical loading conditions.

### Engage Control Sequence

Generally, the central controller can engage a control sequence to initiate operational readiness of the hybrid-cooled load bank rack with solid-state fast varying load simulator. In one implementation, engaging the control sequence can include activating one or more safety interlocks to prevent unintended energization and/or hazardous conditions during load simulation. The central controller can commence a runtime timer (e.g., a hardware timer, a software timer, and/or a combination thereof) to record elapsed time from the start of a simulation sequence, thereby enabling time-based control and/or logging of load bank operation. Additionally, the central controller can transmit an initial set of switching commands to the solid-state relay switching assembly, where the switching commands can specify activation states, timing parameters, and/or power levels for the power semiconductor devices. In one embodiment, the control sequence can further include executing self-diagnostic checks of the solid-state relay switching assembly and/or confirming communication with load bank subsystems prior to commencing dynamic load simulation. Thus, engaging the control sequence can establish a baseline operational state for subsequent modulation of load bank power and cooling system evaluation.

### Modulate Power Through Switching Elements

Generally, modulating power through switching elements can include actuating fast-switching solid-state relays (SSRs) and/or other electronic switching elements within the solid-state relay switching assembly to control power delivery to one or more load banks. The central controller can generate and/or receive control signals derived from a time-versus-power profile, such as profiles representative of real-world server rack power consumption patterns including rapid fluctuations characteristic of AI training and/or inference workloads. The SSRs can be toggled and/or pulse-width modulated (PWM) at frequencies sufficient to achieve sub-millisecond response times (e.g., temporal resolution up to at least 20 kHz), enabling the hybrid-cooled load bank rack to simulate bursty and/or fast-varying load conditions. More specifically, modulation parameters such as switching frequency, duty cycle, and/or phase can be adjusted to match arbitrary and/or user-defined load profiles. The modulating step can be performed for individual load banks and/or groups of load banks, and can be coordinated across both air-cooled and liquid-cooled units within the hybrid-cooled load bank rack. Additionally, inline current sensors within the solid-state relay switching assembly can monitor instantaneous current and/or voltage at the SSRs to verify that actual power delivered closely tracks the target profile, and this measurement data can optionally be fed to the central controller and/or to external systems such as cooling distribution unit (CDU) controllers for coordinated thermal management. The modulation can be performed continuously and/or in discrete intervals, and can be adapted in real time based on feedback from the sensor suite and/or external control systems. Thus, the step of modulating power through switching elements addresses the technical challenge of accurately mimicking fast-varying, bursty power demand patterns characteristic of AI workloads, which conventional stepwise or flat on/off load banks cannot achieve.

### Balance Liquid and Air Load Allocation

Generally, the central controller can dynamically allocate the total commanded electrical power between the liquid-cooled load bank module and the air-cooled load bank module according to a configured and/or programmable percentage split. In one implementation, the central controller can continuously monitor the operational status and capacity of each load bank module and can adjust the power allocation in real time to maintain a target proportion while compensating for any module that reaches a maximum and/or minimum power handling capability. The allocation process can utilize feedback from sensors measuring instantaneous power, temperature, and/or flow rates associated with each cooling path. Additionally, the central controller can issue control signals to the solid-state relay switching assembly to modulate the power delivered to each load bank module according to the determined allocation. The allocation algorithm can be updated at a fixed interval and/or in response to detected changes in load demand and/or module status. In some implementations, the allocation can be further refined based on predefined load profiles, real-world server rack demand traces, and/or user-specified test scenarios. The step of balance liquid and air load allocation can also include logic to prevent overloading of any individual module and to ensure safe operation under all tested conditions.

### Adjust Load Based on Cooling Feedback

Generally, the central controller can dynamically adjust the power load profile applied to one or more load banks of the hybrid-cooled load bank rack based on real-time feedback from cooling system sensors. More specifically, the central controller can modify the switching commands sent to the solid-state relay switching assembly in response to measured parameters such as inlet and outlet coolant temperatures, air temperatures, and/or feedback signals from a cooling distribution unit via the CDU feedback interface. In one implementation, the central controller can implement closed-loop control algorithms, such as proportional-integral-derivative (PID) control and/or model-predictive control (MPC), to ensure that thermal operating limits of the load banks and/or the cooling system are approached but not exceeded. Additionally, the central controller can continuously monitor temperature and/or flow rate data from sensors positioned at critical points in the liquid and air cooling circuits, and can calculate an allowable power ramp rate and/or maximum instantaneous load that can be applied without exceeding predefined thermal thresholds. The switching commands to the power semiconductor devices can be updated in real time (e.g., at configurable intervals ranging from approximately 10 milliseconds to several seconds) to modulate the electrical load accordingly. In another implementation, the central controller can receive feedback from the cooling distribution unit regarding available cooling capacity and/or pressure drop, and can use this information to further refine the load adjustment strategy. Thus, by adjusting the load based on cooling feedback, the system can simulate realistic, fast-varying server rack power demands while maintaining safe thermal operation, thereby addressing the challenge of evaluating the interaction between variable electrical loading and both liquid and air cooling paths in a single rack-level apparatus.

### Monitor System Metrics

The sensor suite can monitor system metrics by acquiring electrical and/or thermal data from sensors distributed throughout the hybrid-cooled load bank rack with solid-state fast varying load simulator during operation. In one implementation, the monitoring can include sampling instantaneous power consumption at the outputs of the solid-state relay switching assembly, as well as measuring temperatures, flow rates, and/or pressure drops at both the liquid-cooled load bank module and the air-cooled load bank module. The collected data can be processed locally by the central controller and/or transmitted in real time to external systems via the communication interface. Additionally, the monitoring can include logging data for post-test analysis, generating alerts if measured values exceed predefined thresholds, and/or supporting feedback control loops for automated system response. Sampling rates and/or data selection criteria can be configured to match the temporal resolution required for simulating fast-varying server rack power loads, such as those encountered in AI training and/or inference environments.

### Capture Instantaneous Electrical Load Data

Generally, the inline current sensors can capture instantaneous electrical load data from each output channel of the solid-state relay switching assembly. In one implementation, the sensors can measure electrical parameters including voltage, current, and/or true power at a sampling rate (e.g., at least 10,000 samples per second) to enable high-fidelity characterization of dynamic load events. Each measurement sample can be associated with a time-stamp to support accurate temporal correlation with load profile events and/or thermal responses. The captured data can be logged to a local storage device associated with the central controller and/or processed to derive additional metrics, such as power factor, apparent power, and/or energy consumption over defined intervals. Thus, the capture of instantaneous electrical load data can support simulation and validation of fast-varying power demands characteristic of AI server rack environments.

### Capture Cooling System Parameters

The system can capture cooling system parameters by acquiring and/or recording operational data from the hybrid-cooled server rack at a target temporal resolution (e.g., 100 milliseconds or less). The pressure/flow sensors of the fluid manifold assembly can measure and/or log the temperature of the liquid coolant at the inlet and/or outlet of the rack, the volumetric flow rate of the liquid coolant, and/or the differential pressure across the rack. Additionally, or alternatively, the airflow and temperature sensors of the air-cooled load bank module can capture the temperature of the air at the inlet and/or outlet of the rack. The captured parameters can be synchronized with the application of variable electrical loads to support characterization of the thermal and/or hydraulic performance of the cooling system under simulated fast-varying power loads, enable real-time feedback to control systems, and/or support post-test analysis of cooling system response. In implementations, additional parameters such as humidity, coolant conductivity, and/or air velocity can also be captured depending on the configuration of the hybrid-cooled load bank system. The capture cooling system parameters step can output a cooling system parameter dataset that serves as an input to subsequent data streaming and/or analysis operations.

### Stream Data to External Control Systems

Generally, the communication interface can stream data to external control systems by transmitting telemetry data over one or more standard industrial communication protocols. The transmitted data can include an instantaneous electrical load dataset and/or a cooling system parameter dataset, which can be formatted into protocol-compliant packets (e.g., Modbus TCP, BACnet, and/or Profibus packets). In one implementation, the communication interface can timestamp the telemetry data and/or apply error-checking mechanisms to ensure reliable delivery to the external control systems. The external control systems can include cooling distribution units (CDUs), building management systems (BMS), and/or other facility-level controllers, which can utilize the received telemetry to dynamically adjust operational parameters such as pump speed, chiller set-points, and/or valve positions. Alternatively, the transmission can be continuous, periodic, and/or event-driven depending on requirements of a test scenario and/or capabilities of the external control system. Thus, streaming data to external control systems enables coordinated testing of cooling infrastructure under simulated fast-varying load conditions, addressing the challenge of generating and applying arbitrary server load profiles while simultaneously feeding instantaneous power measurements to CDU control systems.

### Analyze Cooling Performance

Generally, the central controller can analyze cooling performance based on the real-time power and thermal telemetry dataset acquired during simulation of fast-varying power loads. More specifically, the central controller can quantify the cooling capacity of the hybrid-cooled load bank rack by calculating a maximum heat removal rate achieved by the combined liquid-cooled load bank module and/or air-cooled load bank module under various load conditions. The central controller can also determine a thermal response time, which can correspond to an elapsed duration between a change in electrical load and a corresponding stabilization of coolant temperature and/or exhaust air temperature within a specified tolerance (e.g., between 0.5 and 2 degrees Celsius). Additionally or alternatively, the central controller can evaluate pressure-drop behavior across the liquid and/or air-cooling circuits by comparing measured inlet and outlet pressures under different flow rates and/or load scenarios. The central controller can further identify discrepancies between commanded load profiles generated by the programmable load profile engine and actual electrical power delivered to the load banks, such as by comparing control signals to real-time power measurements captured by the inline current sensors and/or power measurement sensors. Thus, the analyze cooling performance step can facilitate comprehensive characterization of cooling system behavior in response to dynamic electrical loads.

### Correlate Load and Thermal Data

Generally, the central controller can correlate load and thermal data by aligning time-synchronized electrical power consumption measurements from one or more load banks with corresponding temperature and/or coolant flow-rate data collected from sensors positioned within the hybrid-cooled load bank rack with solid-state fast varying load simulator. More specifically, the correlation can enable extraction of step-response and/or frequency-response characteristics of the cooling system by analyzing how changes in electrical load affect thermal parameters such as coolant inlet temperature, coolant outlet temperature, air exhaust temperature, and/or flow rate. In one implementation, the central controller can apply signal processing techniques, such as cross-correlation and/or transfer function analysis, to quantify the dynamic relationship between power input profiles and resulting thermal responses. Additionally or alternatively, the correlation can be performed in real time to provide immediate feedback to a control system, or the correlation can be executed post-process for detailed system characterization. Further, the central controller can receive synchronized data streams from power measurement sensors, temperature sensors, and/or pressure/flow sensors distributed throughout the hybrid-cooled load bank rack with solid-state fast varying load simulator. In one embodiment, the analysis can distinguish between responses attributable to the liquid-cooled load bank module and responses attributable to the air-cooled load bank module, thereby enabling separate and/or combined evaluation of cooling performance under varying load conditions. Thus, the correlation of load and thermal data can produce load-thermal correlation metrics that quantify the cooling system response to dynamic electrical load patterns.

### Determine Cooling Limits and Response

Generally, the central controller can determine cooling limits and response by evaluating performance of the hybrid-cooled load bank rack under simulated fast-varying power loads to characterize maximum sustainable electrical load, time required to reach specified temperature thresholds, and/or identification of system bottlenecks. More specifically, determining cooling limits and response can include incrementally increasing the electrical load delivered to liquid-cooled and/or air-cooled load bank module via the solid-state relay switching assembly while continuously recording coolant inlet and outlet temperatures, air exhaust temperatures, coolant flow rates, air flow rates, and/or pressure drops across the cooling distribution units, fluid manifold assembly, and/or load banks. The central controller can calculate a maximum load (e.g., between 100 kW and 1 MW) at which the system maintains all monitored temperatures below predefined safety or operational thresholds, and can determine a time (e.g., between 30 seconds and 10 minutes) required for the system to reach thermal equilibrium or to recover from a thermal excursion. Additionally, bottlenecks such as insufficient pump head, inadequate airflow, and/or excessive pressure drop can be identified by analyzing deviations from expected temperature or flow profiles, or by observing inability to maintain target temperatures under increasing load. In one implementation, determining cooling limits and response can be performed for various combinations of liquid-cooled and air-cooled load bank module, and under different cooling fluid temperatures (e.g., between 15° C. and 45° C.) and/or airflow conditions, to fully characterize the cooling response and limitations of the hybrid-cooled load bank system, with the results stored in the cooling limit and response dataset.

### Document Test Results

Generally, the central controller can document test results by aggregating and organizing data generated during the simulation of fast-varying power loads. In one implementation, the central controller can compile time-series measurements of electrical power consumption, temperature, pressure, and/or flow rates for both liquid-cooled and air-cooled subsystems into a structured test report. The central controller can further generate plots of power versus time, cooling performance metrics, and/or system response characteristics under various simulated load conditions. Additionally or alternatively, the central controller can perform statistical analyses on the collected data, such as mean, variance, and/or transient response times, to quantify behavior of the hybrid-cooled load bank rack. Pass/fail criteria for commissioning and/or validation can be applied based on predefined thresholds for parameters such as maximum allowable temperature, pressure drop, and/or deviation from target load profiles. The structured test report can include raw data, processed statistics, graphical representations, and/or compliance assessments formatted to facilitate traceability, reproducibility, and comparison across different test scenarios and/or system configurations.

We claim:

1. A hybrid-cooled load bank rack with solid-state fast varying load simulator, comprising:
a rack frame configured to house air-cooled and liquid-cooled load bank module;
at least one liquid-cooled load bank module mounted within the rack frame;
at least one air-cooled load bank module mounted within the rack frame;
a solid-state relay switching assembly electrically coupled to the at least one liquid-cooled load bank module and the at least one air-cooled load bank module, the solid-state relay switching assembly comprising power semiconductor devices configured for sub-millisecond switching response;
a central controller configured to generate control signals to modulate power delivered to the at least one liquid-cooled load bank module and the at least one air-cooled load bank module according to a time-versus-power profile; and
a sensor suite configured to measure electrical and thermal parameters during operation.

2. The hybrid-cooled load bank rack of claim 1, wherein:
the solid-state relay switching assembly further comprises a gate driver and snubber network configured to provide optically isolated gate driver circuits and suppress voltage transients.

3. The hybrid-cooled load bank rack of claim 1, wherein:
the solid-state relay switching assembly further comprises inline current sensors configured to measure instantaneous current at each output of the power semiconductor devices.

4. The hybrid-cooled load bank rack of claim 1, wherein:
the central controller comprises a programmable load profile engine configured to generate the control signals with a temporal resolution of less than 1 millisecond.

5. The hybrid-cooled load bank rack of claim 1, wherein:
the at least one liquid-cooled load bank module comprises a liquid heat exchange assembly having fluid channels thermally bonded to resistive heating elements.

6. The hybrid-cooled load bank rack of claim 5, wherein:
the at least one liquid-cooled load bank module further comprises coolant quick-disconnect couplings configured to enable connection and disconnection of liquid cooling lines without draining a cooling circuit.

7. The hybrid-cooled load bank rack of claim 1, further comprising:
a fluid manifold assembly comprising flow control valves configured to regulate a coolant flow rate to individual load bank modules.

8. The hybrid-cooled load bank rack of claim 1, further comprising:
a CDU feedback interface configured to transmit instantaneous electrical load measurements to an external cooling distribution unit.

9. The hybrid-cooled load bank rack of claim 1, wherein:
the central controller comprises a communication interface configured to transmit operational data via Ethernet or Modbus-TCP protocols.

10. The hybrid-cooled load bank rack of claim 1, wherein the sensor suite comprises:
power measurement sensors configured to monitor true RMS voltage, current, and power for each load bank module;
temperature sensors positioned at coolant inlets and coolant outlets; and
pressure sensors configured to measure differential pressure across a liquid cooling circuit.

11. A method for simulating fast-varying hybrid-cooled server rack power loads, comprising:
preparing a hybrid load bank environment by installing a liquid-cooled load bank module and an air-cooled load bank module within a rack frame;
defining a target power profile comprising a time-versus-power dataset;
encoding the target power profile into control signals for a set of solid-state relays;
applying the target power profile by modulating power through the set of solid-state relays to the liquid-cooled load bank module and the air-cooled load bank module; and
monitoring system metrics including instantaneous electrical load and cooling system parameters.

12. The method of claim 11, wherein applying the target power profile further comprises:
balancing liquid and air load allocation by dynamically allocating power between the liquid-cooled load bank module and the air-cooled load bank module according to a configured percentage split.

13. The method of claim 11, wherein applying the target power profile further comprises:
adjusting load based on cooling feedback by modifying switching commands in response to measured coolant temperatures or feedback from a cooling distribution unit.

14. The method of claim 11, wherein defining the target power profile comprises:
acquiring or generating a power demand dataset representative of AI training or inference server workloads with sub-second granularity.

15. The method of claim 11, wherein monitoring system metrics comprises:
capturing instantaneous electrical load data at a sampling rate of at least 10,000 samples per second; and
capturing the cooling system parameters including coolant temperature, flow rate, and differential pressure at intervals of 100 milliseconds or less.

16. The method of claim 11, further comprising:
streaming data to an external control system by transmitting power telemetry to a cooling distribution unit controller.

17. The method of claim 11, further comprising:
analyzing cooling performance by correlating load data and thermal data to extract step-response characteristics of a cooling system.

18. The method of claim 17, wherein analyzing cooling performance further comprises:
determining cooling limits and response by identifying a maximum sustainable electrical load and thermal response times.

19. The method of claim 11, wherein preparing the hybrid load bank environment comprises:
configuring a load bank composition by selecting a proportion of liquid-cooled modules relative to air-cooled modules;
connecting power and cooling interfaces; and
initializing sensors and controllers including calibrating power meters and zeroing temperature sensors and pressure sensors.

20. The method of claim 11, wherein encoding the target power profile into the control signals comprises:
generating pulse-width modulation signals or phase-angle control signals with microsecond-scale temporal resolution.
